(19) United States
(12) Patent Application Publication
(10) Pub. No.: US 2026/0262482 A1
(43) Pub. Date: Sep. 3, 2026

(54) METHOD FOR PRODUCING HYDROPHILIZED PRODUCT

(71) Applicant: Resonac Corporation, Minato-ku, Tokyo (JP)

(72) Inventors: Motohiro ARIFUKU, Tokyo (JP); Keita SONE, Tokyo (JP); Ryutaro NAGATA, Tokyo (JP)

(21) Appl. No.: 19/163,011

(22) PCT Filed: Mar. 10, 2023
(86) PCT No.: PCT/JP2023/009411

§ 371 Date: Sep. 8, 2025

(51) Int. Cl. H10P 95/70; C01B 33/12; C01F 7/448; C01F 17/235; H10P 90/00; H10P 95/90

(52) U.S. Cl. CPC H10P 95/70; C01B 33/12; C01F 7/448; C01F 17/235; H10P 90/1904; H10P 95/90; C01P 2004/62

(57) ABSTRACT

A method for producing a hydrophilized product according to one aspect of the present disclosure includes a step of subjecting an object to be treated having an inorganic oxide on a surface thereof and an alkaline reaction liquid including water to hydrothermal treatment, to hydrophilize the inorganic oxide.

### TECHNICAL FIELD

The present disclosure relates to a method for producing a hydrophilized product.

### BACKGROUND ART

Oxide particles such as silica and alumina are widely used as inorganic fillers for electronic materials and resin members for automobiles (for example, Patent Literature 1).

### CITATION LIST

### Patent Literature

Patent Literature 1: Japanese Unexamined Patent Publication No. 2020-132753

### SUMMARY OF INVENTION

### Technical Problem

Meanwhile, inorganic oxides are required to have high hydrophilicity.

An object of the present disclosure is to provide a method for producing a novel hydrophilized product capable of hydrophilizing an inorganic oxide.

### Solution to Problem

One aspect of the present disclosure is a method for producing a hydrophilized product, the method including a step of subjecting an object to be treated having an inorganic oxide on a surface thereof and an alkaline reaction liquid including water to hydrothermal treatment, to hydrophilize the inorganic oxide.
[1] A method for producing a hydrophilized product, the method including a step of subjecting an object to be treated having an inorganic oxide on a surface thereof and an alkaline reaction liquid including water to hydrothermal treatment, to hydrophilize the inorganic oxide.
[2] The method for producing the hydrophilized product according to [1], in which the inorganic oxide is alumina.
[3] The method for producing the hydrophilized product according to [1] or [2], in which the inorganic oxide is silica.
[4] The method for producing the hydrophilized product according to any one of [1] to [3], in which the inorganic oxide is ceria.
[5] The method for producing the hydrophilized product according to any one of [1] to [4], in which the hydrothermal treatment is performed under a condition of a temperature of 110° C. to 300° C.
[6] The method for producing the hydrophilized product according to any one of [1] to [5], in which the hydrothermal treatment is performed under conditions of a temperature of 110° C. to 190° C. and a treatment time of 5 minutes to 24 hours.
[7] The method for producing the hydrophilized product according to any one of [1] to [6], in which the object to be treated is particles.
[8] The method for producing the hydrophilized product according to any one of [1] to [6], in which the object to be treated is a semiconductor wafer.

### Advantageous Effects of Invention

According to one aspect of the present disclosure, there is provided a method for producing a novel hydrophilized product capable of hydrophilizing an inorganic oxide.

### DESCRIPTION OF EMBODIMENTS

Hereinafter, the present disclosure will be described in detail in accordance with preferred embodiments thereof. However, the present disclosure is not limited to the following embodiments.

In the present specification, the term “step” includes not only an independent step but also a step that cannot be clearly distinguished from other steps as long as an intended action of the step is achieved. In the present specification, a numerical range indicated using “to” indicates a range including numerical values respectively described before and after “to” as a minimum value and a maximum value. In the numerical range described in stages in the present specification, an upper limit value or a lower limit value of a numerical range of a certain stage can be arbitrarily combined with an upper limit value or a lower limit value of a numerical range of another stage. In the numerical range described in the present specification, the upper limit value or the lower limit value of the numerical range may be replaced with a value shown in Examples. “A or B” only needs to include either A or B, and may include both A and B. Materials exemplified in the present specification can be used alone or in combination of two or more unless otherwise specified.

### (Method for Producing Hydrophilized Product)

A method for producing a hydrophilized product according to the present embodiment includes a step of subjecting an object to be treated having an inorganic oxide on a surface thereof and an alkaline reaction liquid including water to hydrothermal treatment, to hydrophilize the inorganic oxide.

An area ratio of the inorganic oxide to the surface of the object to be treated may be 50% or more, 60% or more, 70% or more, 80% or more, 90% or more, or 100%.

A shape of the object to be treated is not particularly limited as long as the object to be treated can be accommodated in a sealed container and water and an alkaline agent can come into contact with the surface of the object to be treated. Examples of the shape of the object to be treated include a tubular shape, a columnar shape, a spherical shape, an indefinite shape, and a plate shape. The object to be treated may be particles. The object to be treated may be a semiconductor wafer.

The inorganic oxide includes an element that is less electronegative than oxygen and forms at least one divalent or higher ion.

Examples of the inorganic oxide include silica, ceria, alumina, titania, zirconia, magnesia, yttria, zinc oxide, iron oxide, tin oxide, scandium oxide, vanadium oxide, and chromium oxide. The inorganic oxide may be a double oxide including two or more kinds of metals. As such a double oxide, for example, inorganic oxides such as lithium titanate, barium titanate, and magnesium aluminum oxide may be prepared by, for example, a melting method, a sol-gel method, a liquid phase method, or the like.

The reaction liquid is alkaline. Alkaline means that pH is greater than 7.0. The reaction liquid may be adjusted to be alkaline by adding the alkaline agent to water. A saturated vapor pressure of the alkaline agent is preferably lower than that of water because a pressure resistance of the sealed container tends to be lowered. Examples of the alkaline agent having a saturated vapor pressure higher than that of water include amines such as ammonia and methylamine. Examples of the alkaline agent having a saturated vapor pressure lower than that of water include metal hydroxides such as potassium hydroxide, sodium hydroxide, and aluminum hydroxide. In addition, a solid base catalyst such as zeolite having a surface subjected to alkali treatment may be used as the alkaline agent.

The pH of the reaction liquid is more than 7.0, may be 8.0 or more, 9.0 or more, 10.0 or more, or 11.0 or more, and may be 13.0 or less.

The hydrothermal treatment can be performed by enclosing the object to be treated in a pressure-resistant sealed container together with water and the alkaline agent, and heating the object to be treated at a temperature exceeding 100° C. in a sealed state. When the reaction liquid including the object to be treated and water is heated in the sealed container, an inside of the sealed container becomes a heated and pressurized environment, and the hydrothermal treatment (hydrothermal synthesis) is performed.

The hydrothermal treatment may be performed by supplying water vapor (steam) from an outside into the sealed container. By supplying water vapor from the outside, the inside of the sealed container can be raised in temperature and pressure in a short time, and a hydrothermal treatment environment can be easily formed and maintained. Water vapor can be supplied by using, for example, a boiler. Water vapor may be supplied in combination with a method of heating the reaction liquid including the object to be treated and water in the sealed container. A supply amount of water vapor is appropriately adjusted so that the inside of the sealed container has a predetermined temperature and pressure.

The hydrothermal treatment may be performed while stirring the reaction liquid. As the pressure-resistant sealed container, a known container that can be used for the hydrothermal treatment can be used without particular limitation. As the pressure-resistant sealed container, for example, an autoclave can be used.

A content of the object to be treated in the reaction liquid is not particularly limited as long as a sufficient amount of water for performing the hydrothermal treatment can be secured, but may be 10 parts by volume or more, 20 parts by volume or more, or 50 parts by volume or more, and may be 300 parts by volume or less, 200 parts by volume or less, or 100 parts by volume or less with respect to 100 parts by volume of water. The content of the object to be treated in the reaction liquid is preferably 100 parts by volume or less because viscosity of the reaction liquid is not too high, the reaction liquid tends to be easily stirred, and treatment efficiency tends to be improved.

Reaction conditions of the hydrothermal treatment are not particularly limited, and can be set to, for example, 110° C. to 300° C. for 0.5 minutes to 24 hours. When the reaction temperature is 110° C. or higher, the hydrothermal reaction tends to occur more favorably, and when the reaction temperature is 300° C. or lower, ion concentration in the reaction liquid is high, and the reaction tends to proceed in a short time. The reaction temperature is preferably 170° C. or higher, preferably 260° C. or lower, and more preferably 190° C. or lower. Reaction time is preferably 5 minutes to 24 hours, more preferably 0.5 to 24 hours, and still more preferably 5 to 15 hours. When the reaction time is 24 hours or less, progress of the reaction and cost tend to be easily balanced.

The hydrothermal treatment is preferably performed under conditions of a low temperature (for example, lower than 250° C.) and a long time (for example, 1 hour or more) because hydrophilicity is further improved. When the reaction temperature is lower than 250° C., bumping of the reaction liquid is less likely to occur at the time of cooling after the reaction, and there is a tendency that it is possible to suppress a decrease in yield of the hydrophilized product due to scattering of the reaction liquid outside the container by the bumping. When the reaction temperature is lower than 250° C., there is a tendency that cooling time of the reaction liquid is shortened and operation efficiency can be improved. Further, when the reaction time is 1 hour or more, hydrophilization reaction tends to proceed sufficiently even at a low temperature.

The pressure in the container during the hydrothermal treatment only needs to be a saturated vapor pressure corresponding to the reaction temperature or higher, and is preferably the saturated vapor pressure from the viewpoint of pressure resistance of a device. When water vapor is supplied into the sealed container, it is preferable to supply saturated water vapor at the reaction temperature described above.

### (Hydrophilicity Evaluation by Hansen Solubility Index (HSP))

In the present specification, the inorganic oxide being hydrophilized means that a value of at least one of a polarization force term (δₚ₁) and a hydrogen bonding force term (δₕ₁) of a Hansen solubility index is higher by 2 or more than that of an untreated inorganic oxide.

In the past, as a method for evaluating hydroxyl group concentration and hydrophilicity on an inorganic oxide surface, a surface infrared spectrum measurement method, a titration method using a metal hydride or an organometallic compound, and the like have been known, but there have been problems that reproducibility is low and quantitativeness is poor due to accuracy, required humidity, strict management of water content, and the like. Therefore, as a result of intensive studies, the inventors have found that the following HSP measurement method is a hydrophilicity evaluation method capable of satisfying quantitativity and reproducibility.

Specifically, since there is a known information source such as a database for δ_{d}, δₚ, and δₕ of a generally used substance, for example, δ_{d}, δₚ, and δₕ of a desired substance can be obtained by referring to the database. Parameters of a substance not registered in the database can be calculated using, for example, computer software such as Hansen Solubility Parameter in Practice; written by Prof. Steven Abbott and Dr. Yamamoto Hiroshi (HSPiP).

For example, δ_{d1}, δₚ₁, and δₕ₁ of an inorganic oxide particle can be calculated by the following procedure. First, 16 types of evaluation solvents with known parameters (δ_{d}, δₚ, and δₕ) are prepared. Subsequently, a dispersibility test of particles to be evaluated with respect to each evaluation solvent is performed, and it is determined whether each evaluation solvent is either “solvent having excellent dispersibility” or “solvent having poor dispersibility”. The dispersibility test can be performed by a method shown in Examples described later. Subsequently, each evaluation solvent is plotted in a three-dimensional space (Hansen space) having δ_{d}, δₚ, and δₕ as coordinate axes, and then a virtual true sphere including all of the “solvent having excellent dispersibility” without including all of the “solvent having poor dispersibility” is created in the three-dimensional space. Then, δ_{d}, δₚ, and δₕ at a center of the true sphere can be obtained as δ_{d1}, δₚ₁, and δₕ₁ of the particle.

δ_{d1}, δₚ₁, and δₕ₁ vary depending on material type, particle size, particle size distribution (coefficient of variation of particle size), surface treatment contents (type of surface treatment agent, amount of surface treatment agent used, surface treatment method, and the like), and the like of the particle. For example, as the particle size is larger, δ_{d1} tends to increase, and δₚ₁ and δₕ₁ tend to decrease. In addition, as the coefficient of variation of the particle size is larger, δₚ₁ tends to increase and δₕ₁ tends to decrease. δ_{d1}, δₚ₁, and δₕ₁ of the particle after the surface treatment are for the entire particles after the surface treatment in consideration of influence of the surface treatment. As δ_{d1}, δₚ₁, and δₕ₁, numerical values at 25° C. can be used.

### EXAMPLES

Hereinafter, the present disclosure will be described more specifically based on Examples and Comparative Examples, but the present disclosure is not limited to the following Examples.

### Example 1

Alumina particles (trade name “AA04” manufactured by Sumitomo Chemical Co., Ltd.) were prepared as the object to be treated. Based on real image observation using a scanning electron microscope (SEM), a particle size D50 (hereinafter, referred to as “particle size A”) and a particle size D100 of the particles were obtained. The particle size A was 0.4 μm.

18 g of the alumina particles (particle size A: 0.4 μm) was dispersed in 162 g of ultrapure water, and a predetermined amount of sodium hydroxide was added while confirming the pH of dispersion with a pH meter (manufactured by As One Corporation) to prepare a reaction liquid 1 having a pH of 12. This was enclosed in a Teflon (registered trademark) container having a volume of 200 ml, the Teflon (registered trademark) container was further housed in a stainless pressure-resistant container, and the pressure-resistant container was sealed. In the sealed pressure-resistant container, solution in the Teflon (registered trademark) container was heated with a heater so that the temperature of the reaction liquid was 180° C. while being stirred at a rotation speed of 700 rpm using a magnetic stirrer. After reaching 180° C., the hydrothermal treatment was performed at 180° C. for 5 hours while continuing stirring. Thereafter, heating and stirring were stopped, and the reaction liquid was naturally cooled to normal temperature (25° C.). Note that a maximum reaching temperature of the reaction liquid during the hydrothermal treatment was 181° C. After cooling, the solution and solids in the Teflon (registered trademark) container were taken out into a beaker, ultrapure water was added to dilute the solution to 800 ml, the solution was allowed to stand overnight to precipitate the alumina particles, and supernatant was separated with a dropper. Dilution and separation were repeated until the pH of the supernatant was 7. Thereafter, the supernatant was dried in an oven at 130° C. for 3 hours to obtain 15.6 g of powdered alkaline hydrothermally reacted alumina 1.

### Example 2

Silica particles (trade name “KE-S50” manufactured by Nippon Shokubai Co., Ltd.) were prepared. Based on real image observation using a scanning electron microscope (SEM), a particle size D50 (hereinafter, referred to as “particle size A”) and a particle size D100 of the particles were obtained. The particle size A was 0.5 μm. Powdered alkaline hydrothermally reacted silica 1 was obtained in the same manner as in Example 1 except that silica particles (trade name “KE-S50” manufactured by Nippon Shokubai Co., Ltd., particle size A: 0.5 μm) were used instead of the alumina particles.

### Comparative Example 1

Untreated alumina particles were used as a sample of Comparative Example 1.

### Comparative Example 2

18 g of the alumina particles (trade name “AA04” manufactured by Sumitomo Chemical Co., Ltd., particle size A: 0.4 μm) was dispersed in 162 g of ultrapure water, and a predetermined amount of sulfuric acid was added while confirming the pH of dispersion with the pH meter (manufactured by As One Corporation) to prepare a reaction liquid 2 having a pH of 7. Hydrothermally reacted alumina particles 2 were obtained in the same manner as in Example 1 except that the reaction liquid 2 was used instead of the reaction liquid 1.

### Comparative Example 3

Untreated silica particles were used as a sample of Comparative Example 3.

### Comparative Example 4

18 g of the silica particles (trade name “KE-S50” manufactured by Nippon Shokubai Co., Ltd., particle size A: 0.5 μm) were dispersed in 162 g of ultrapure water to obtain a reaction liquid 3. The pH of the reaction liquid 3 was 6.9. Hydrothermally reacted silica particles 2 were obtained in the same manner as in Example 1 except that the reaction liquid 3 was used instead of the reaction liquid 1.

### <Evaluation Method>

### (Measurement of Hansen Solubility Index of Sample)

Next, 0.02 g of particles were respectively placed in 16 containers (screw bottles), and then 20 mL of 16 types of organic solvents were respectively placed in the containers to prepare test solutions (particle content: about 0.1 mass %). As the 16 types of organic solvents, methyl isobutyl ketone (MIBK), toluene, methanol, cyclohexanol, acetone, acetonitrile, formamide, benzyl benzoate, dimethyl sulfoxide, ethyl acetate, ethanol, acetic anhydride, γ-butyrolactone, methyl ethyl ketone (MEK), 1-butanol, and cyclohexane were used. The test solution described above was subjected to dispersion treatment for 5 minutes using an ultrasonic dispersion apparatus (trade name “VS-D100” manufactured by As One Corporation). Subsequently, the particle size distribution (cumulative particle size distribution and volume distribution) of the particles in the test solution was measured using a particle size distribution meter (trade name “SALD-7500” manufactured by Shimadzu Corporation). For each of cases of using the 16 types of organic solvents described above, a particle size D50 (hereinafter, referred to as “particle size B”) was obtained based on measurement results of the particle size distribution. Note that the particle size distribution of standard particles (MBP1-10) having a specified particle size distribution was measured in advance, and it was confirmed that measurement contents were appropriate.

Based on the measurement results of the particle size distribution described above, the coefficient of variation (CV) of the particle size was obtained for each of the cases of using the 16 types of organic solvents described above. A case where the coefficient of variation was 20 or more was determined to be in a polydispersed state, and a case where the coefficient of variation was less than 20 was determined to be in a monodispersed state. With respect to the 16 types of organic solvents described above, it was determined whether the solvent was the “solvent having poor dispersibility” or the “solvent having excellent dispersibility” according to the following criteria.

With respect to a criterion of aggregation in the monodispersed state, a particle size twice as large as the particle size A described above (assuming a particle size when two particles are in contact with each other) was adopted as a threshold value, an organic solvent in a case where the particle size B described above was equal to or more than the threshold value was determined as the “solvent having poor dispersibility”, and an organic solvent in a case where the particle size B described above was less than the threshold value was determined as the “solvent having excellent dispersibility”.

On the other hand, with respect to a criterion of aggregation in the polydispersed state, from the viewpoint that it is desirable to provide a criterion for easily targeting aggregated particles because of a wide distribution of particle sizes, the particle size D100 described above was adopted as a threshold value, an organic solvent in a case where the particle size B described above was equal to or more than the threshold value was determined as the “solvent having poor dispersibility”, and an organic solvent in a case where the particle size B described above was less than the threshold value was determined as the “solvent having excellent dispersibility”.

Next, the 16 types of organic solvents described above were plotted in the three-dimensional space (Hansen space) having δ_{d}, δₚ, and δₕ as the coordinate axes using analysis software Hansen Solubility Parameter in Practice; written by Prof. Steven Abbott and Dr. Yamamoto Hiroshi (HSPiP). As da, &p, and &h of each organic solvent, the numerical values in the database of the analysis software described above were used.

Subsequently, the virtual true sphere including all of the “solvent having excellent dispersibility” described above without including all of the “solvent having poor dispersibility” described above was created in the three-dimensional space described above. Then, δ_{d}, δₚ, and δₕ at the center of the true sphere were obtained as δ_{d1}, δₚ₁, and δₕ₁ of the particle. δ_{d1}, δₚ₁, and δₕ₁ of the particles in Examples and Comparative Examples are shown in Table 1.

TABLE 1

| | Hansen solubility index (HSP) | | |
|---|---|---|---|
| | δ_{d1} | δₚ₁ | δₕ₁ |
| Example 1 | 15.1 | 12.2 | 13.4 |
| Example 2 | 14.0 | 12.9 | 19.4 |
| Comparative | 16.8 | 8.9 | 12.7 |
| Example 1 | | | |
| Comparative | 16.0 | 9.2 | 12.9 |
| Example 2 | | | |
| Comparative | 13.5 | 13.5 | 13.9 |
| Example 3 | | | |
| Comparative | 13.7 | 13.5 | 13.5 |
| Example 4 | | | |

Among three terms of HSP, the terms affecting hydrophilicity are δₚ₁ due to polarization force and δₕ₁ due to hydrogen bonding force. When the value of at least one of these two terms is higher by 2 or more than that of the untreated inorganic oxide, it is considered that the number of hydroxyl groups in the inorganic oxide has increased, and eventually it can be determined that the inorganic oxide has been hydrophilized.

When Example 1 and Comparative Example 1 in which the object to be treated is the alumina particles are compared, it can be seen that the alumina particles are hydrophilized by the hydrothermal treatment in Example 1 since the values of δₚ₁ and δₕ₁ both increase and δₚ₁ increases by 2 or more.

On the other hand, when comparing Comparative Example 1 and Comparative Example 2, since there is almost no change in HSP, it can be seen that the inorganic oxide is not hydrophilized by the hydrothermal treatment under neutral conditions.

Comparing Example 2 and Comparative Example 3 in which the object to be treated is the silica particles, it can be seen that δₕ₁ of δₚ₁ and Shi remarkably increases in Example 2, and the silica particles are hydrophilized by the hydrothermal treatment.

On the other hand, when comparing Comparative Example 3 and Comparative Example 4, since there is almost no change in HSP, it can be seen that the inorganic oxide is not hydrophilized by hydrothermal treatment under acidic conditions.

1. A method for producing a hydrophilized product, the method comprising a step of subjecting an object to be treated having an inorganic oxide on a surface thereof and an alkaline reaction liquid including water to hydrothermal treatment, to hydrophilize the inorganic oxide.

2. The method for producing the hydrophilized product according to claim 1, wherein the inorganic oxide is alumina.

3. The method for producing the hydrophilized product according to claim 1, wherein the inorganic oxide is silica.

4. The method for producing the hydrophilized product according to claim 1, wherein the inorganic oxide is ceria.

5. The method for producing the hydrophilized product according to claim 1, wherein the hydrothermal treatment is performed under a condition of a temperature of 110° C. to 300° C.

6. The method for producing the hydrophilized product according to claim 1, wherein the hydrothermal treatment is performed under conditions of a temperature of 110° C. to 190° C. and a treatment time of 5 minutes to 24 hours.

7. The method for producing the hydrophilized product according to claim 1, wherein the object to be treated is particles.

8. The method for producing the hydrophilized product according to claim 1, wherein the object to be treated is a semiconductor wafer.
